(19) United States
(12) Patent Application Publication
(10) Pub. No.: US 2008/0185671 A1
(43) Pub. Date: Aug. 7, 2008

(54) Sensor semiconductor package and fabrication

(75) Inventors: Chien-Ping Huang, Taichung (TW); Cheng-Yi Chang, Taichung (TW); Chang-Yueh Chan, Taichung (TW)

Correspondence Address: Edwards Angell Palmer & Dodge LLP, P.O. Box 55874, Boston, MA, 02205, US

(73) Assignee: Siliconware Precision Inductries Co., Ltd., Taichung (TW)

(21) Appl. No.: 12/011,933

(22) Filed: Jan. 30, 2008

(30) Foreign Application Priority Data
Feb. 2, 2007 (TW) 096103830
Feb. 11, 2007 (TW) 096120928

(51) Int. Cl. H01L 31/00; H01L 21/00

(52) U.S. Cl. 257/432; 438/64; 257/E21.001; 257/E31.001

(57) ABSTRACT

A sensor semiconductor package and a fabrication method thereof are provided in the present application. The fabrication method comprises steps of: forming a plurality of grooves on a wafer between bond pads on active surfaces of every adjacent chips; forming metal layers in the grooves for electrically connecting with the bond pads of adjacent chips; thinning the non-active surfaces to expose the metal layers therefrom; forming a cover layer on the non-active surfaces with the metal layers are exposed therefrom; forming a solder resist layer on the covering layer and the conductive wirings with terminals of the conductive wirings are exposed therefrom; and cutting along cutting paths between every sensor chips to form a plurality of sensor semiconductor packages. Accordingly, the prior art problems such as misalignment of forming beveled grooves, concentrated stress and breakage can be solved.

### BACKGROUND OF THE INVENTION

1. Field of the Invention

The present invention relates to a sensor semiconductor package and a fabrication method thereof, and more particularly to a sensor semiconductor package at the wafer-level and a fabrication method thereof.

2. Description of the Prior Art

Mainly, a conventional image sensor package as disclosed in U.S. Pat. Nos. 6,384,472 or 6,509,636 is formed by mounting a sensor chip to a chip carrier and electrically connecting the sensor chip to the chip carrier through a bonding wire and followed by covering the sensor chip with a glass to allow the image light to be captured by the sensor chip. Such obtained image sensor package can be integrated to an external device such as a printed circuit board (PCB) for further being incorporated in various kinds of electronic products such as digital cameras, digital videos, optical mice, and mobile phones.

As capacity of information transmission continue to increase, as well as the trend toward miniaturization and portability of electronic products, the desirability of efficient heat dissipation and downsizing are being particularly emphasized, such that the integrated circuit package is developed to have a high electronic functionality and small size. Thus, the industry has developed a wafer-level image sensor package, to directly form the package on the wafer, allowing the sensor chip to be electrically connected to an external device directly,which is favorable in the use of small electronic device.

Referring to FIGS. 1A-1E, a wafer level image sensor semiconductor package disclosed in U.S. Pat. No. 6,646,289 is formed by: providing a wafer 100 having a plurality of image sensor chips 10 with an extending circuit 12 being formed between the bond pads 11 of adjacent sensor chips 10 (as shown in FIG. 1A); attaching a glass 13 on the wafer 100 by an adhesive layer 14 (as shown in FIG. 1B); performing a thinning process on the wafer 100 and after attaching a cover layer 15 on the back of the wafer 100, a beveled groove 16 is formed between the adjacent chips 10, which penetrates the cover layer 15, sensor chip 10 and extending circuits 12 (as shown in FIG. 1C) and stops at the internal of the glass 13 by such as an etch process; forming metal windings 17 on the surface of the beveled groove 16 and surfaces of the cover layer 15 near to the beveled groove 16 to allow the metal windings 17 to be electrically connected to the extending circuit 12 (as shown in FIG. 1D); deposing solder balls 18 on the metal windings 17 above the surfaces of the cover layer 15, followed by a cutting process between the sensor chips 10, so as to finish the fabrication of the wafer-level image sensor package (as shown in FIG. 1E). U.S. Pat. No. 6,777,767 also discloses the similar technique.

However in the forgoing image sensor package, due to the beveled grooves formed on the back of the wafer, the semiconductor package has beveled sides, that is to say, from a cross-sectional upright view the side appears to be an upside down trapezium shape (the horizontal width decreases from top to bottom), such that the metal windings formed at the side surface of the semiconductor package forms a sharp angle contact with the extending wire of the bond pads on the top surface of the chip. This may seriously lead to breakage problem due to concentrated stress. Moreover, as beveled grooves are formed on the back of the wafer, it is difficult to align to the desired position, thus this might cause the disposition of the beveled grooves is shifted S distance from the original cutting line between adjacent chips, as shown in FIG. 2. This may result in failure of forming successful electrical connection between the metal windings and the extending wires, or in more severe case, cause damages to the chips.

Accordingly, there is an urgent need to develop a wafer-level image sensor package and a fabrication method thereof, so as to prevent circuit breakage, as well as poor electrical connection and chip damage as a result of alignment errors for forming the grooves on the back of the wafer.

### SUMMARY OF THE INVENTION

In light of the foregoing drawbacks of the prior art, a primary objective of the present invention is to provide a sensor semiconductor package and a fabrication method thereof for preventing the prior art problems of stress concentration and breakage due to sharp angle of circuit contact point.

Another objective of the present invention is to provide a sensor semiconductor package and a fabrication method thereof for preventing the prior art problems of poor electrical connections and chip damages as a result of errors in positioning grooves on the back surface of the wafer.

In order to achieve the foregoing and other objectives, the fabrication method of the sensor semiconductor packages disclosed in the present invention, comprising the steps of: providing a wafer having a plurality of sensor chips, each of the wafer and the sensor chips having an active surface and an non-active surface opposing thereto, a sensor area and a plurality of bond pads formed on the active surface, and a plurality of grooves formed between the bond pads of the active surfaces of adjacent sensor chips; forming a conductive layer on the active surfaces of the wafer and the grooves; forming a resist layer on the conductive layer with openings corresponding in position to the grooves; electroplating metal layers in the openings of the resist layer, such that the metal layers are filled in the grooves and electrically connected to the bond pads on the active surfaces of adjacent sensor chips; removing the resist layer and a portion of the conductive layer thereunder; attaching a transparent body on the sensor chips to seal the sensor areas; performing a thinning process on the non-active surfaces of the wafer until respective portions of the metal layers are exposed from the non-active surfaces; forming a cover layer having openings on the non-active surfaces of the wafer for exposing the respective portions of the metal layers; forming conductive wirings on the cover layer to electrically connect to the respective portions of the metal layers exposed from the openings of the cover layer; forming a solder resist layer having openings on the cover layer and the conductive wirings for exposing terminals of the conductive wirings for deposing conductive elements thereon; and performing a cutting process cutting between adjacent sensor chips, so as to obtain a plurality of sensor semiconductor packages.

In addition, for increasing the adherence and the insulation between the sensor chips and the metal layers, the following steps could be performed after the grooves are formed between the bond pads on the active surfaces of adjacent sensor chips, which comprises: filling an insulting layer in the grooves of the wafer; forming openings passing through the insulating layer so as to form the metal layers therein and allow the metal layers to electrically connected to the bond pads on the active surfaces of adjacent sensor chips. The subsequent steps are as described above, which comprising: attaching the transparent body on the sensor chips; thinning the wafer to expose the portion of the metal layers; forming the cover layer on the non-active surfaces of the sensor chips with the portion of the metal layers exposed from the cover layer; forming the conductive wirings that are electrically connected to the metal layers on the cover layer; forming the solder resist layer with the terminals of the conductive wirings exposed therefrom on the cover layer and the conductive wirings; deposing the conductive elements; and cutting along paths between the sensor chips for obtaining the sensor semiconductor packages. For example, the insulation layer is made of polyimide.

Through the foregoing fabrication method, a sensor semiconductor package is further provided in the present invention. The sensor semiconductor package comprises: a sensor chip having an active surface and a non-active surface opposing thereto, wherein the active surface is formed with a sensor area and a plurality of bond pads thereon, a groove is formed on a side of the sensor chip and a metal layer is formed in the groove and is electrically connected to the bond pads; a transparent body mounted on the active surface of the sensor chip for sealing the sensor area; a cover layer formed on the non-active surface of the sensor chip and having an opening for exposing a bottom of the metal layers; a conductive wiring formed under the cover layer and electrically connected to the bottom of the metal layers; a solder resist layer formed under the cover layer and conductive wiring and having openings for exposing a terminal of the conductive wiring; and a conductive element formed in the opening of the solder resist layer.

The sensor semiconductor package further comprises a conductive layer formed between the sensor chip and the metal layers. Alternatively, the sensor package further comprises an insulating layer formed between the sensor chip and the metal layers for increasing the adherence and the insulation between the sensor chips and the metal layers. Further, the transparent body is a glass attached to each sensor chip via an adhesive layer, which covers metal layers. The metal layers have a flat bottom, which is flush with the non-active surface of the sensor chip, for providing a good electrical connection with the conductive wirings.

Accordingly, the sensor semiconductor package and the fabrication method thereof disclosed in the present invention, mainly involve forming a plurality of grooves on a wafer having a plurality of sensor chips, at positions between every adjacent sensor chips, and forming metal layers in grooves for electrically connecting the bond pads on the active surfaces of adjacent chips. This is then followed by attaching a transparent body to seal the sensor areas of the sensor chips, and performing a thinning process on the non-active surfaces of the sensor chips until the metal layers are exposed from the non-active surfaces, so as to prevent the position error in the thinning process, as well as position error of the metal layers, which may subsequently cause poor electrical connection of the conductive circuit on one side of the non-active surface of the chip. After that, a cover layer is formed on the non-active surfaces of the wafer and has openings for exposing the metal layers, which is used for forming conductive wirings on the cover layer, where the conductive wirings formed is allowed to electrically connect to the portion of the metal layers exposing from the openings of the cover layer. A solder resist layer is subsequently formed on the cover layer and the conductive wirings, and has openings for exposing terminals of the conductive wirings, that is exposed for deposing conductive elements thereon. After a cutting process is performed between each adjacent sensor chips, a plurality of sensor semiconductor packages are obtained.

As such, the problem of poor electrical connection of the circuits or even damages in chips due to a shift in position for forming the grooves on the back side of the wafer in the prior art and can be prevented. Moreover, the problem of breakage due to concentrated stress as a result of a sharp contact between the side surface of the semiconductor chip and the active surface of the wiring connecting point in the condition of a beveled side surface of the package can be also prevented.

### BRIEF DESCRIPTION OF THE DRAWINGS

The present invention can be more fully understood by reading the following detailed description of the preferred embodiments, with reference made to the accompanying drawings, wherein:

FIGS. 1A to 1E (PRIOR ART) are schematic views showing a wafer-level image sensor semiconductor package and a fabrication method thereof disclosed in U.S. Pat. No. 6,646,289;

FIG. 2 (PRIOR ART) is a schematic view showing a shift in position of grooves formed on the back surface of a wafer in accordance with a fabrication method of a conventional sensor semiconductor package;

FIGS. 3A to 3I are schematic views showing a sensor package and a fabrication method thereof in accordance with a preferred embodiment of the present invention;

FIGS. 4A to 4F are schematic views showing a sensor package and a fabrication method thereof in accordance with another preferred embodiment of the present invention.

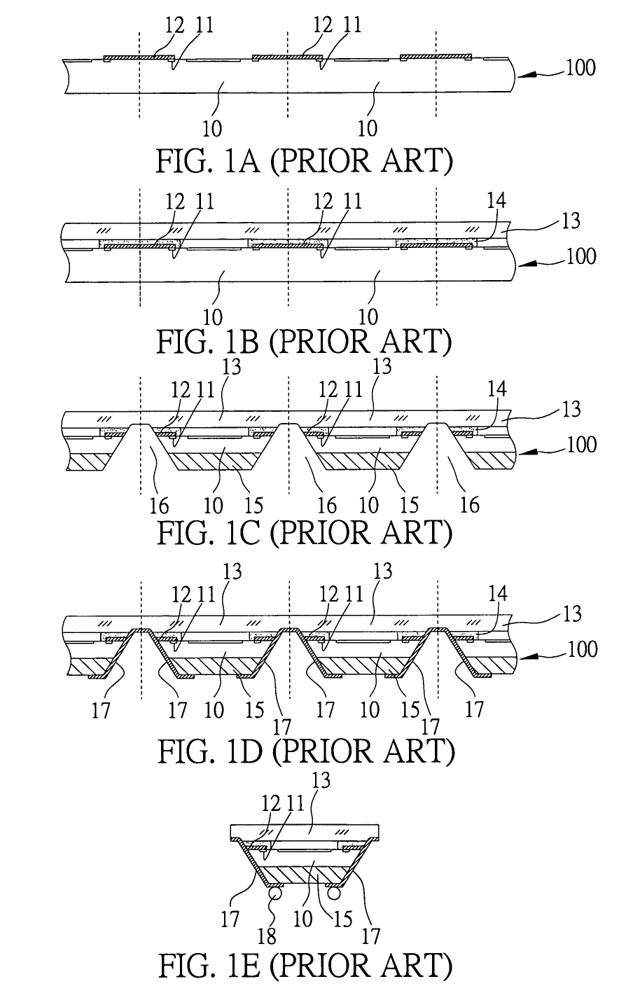

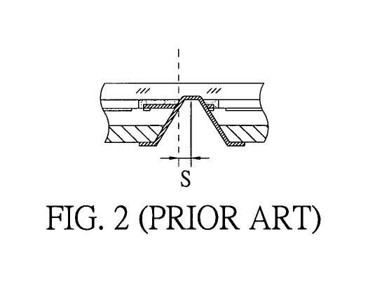

### DETAILED DESCRIPTION OF THE PREFERRED EMBODIMENTS

The present invention is described in the following with specific embodiments, so that one skilled in the pertinent art can easily understand other advantages and effects of the present invention from the disclosure of the present invention.

### First Embodiment

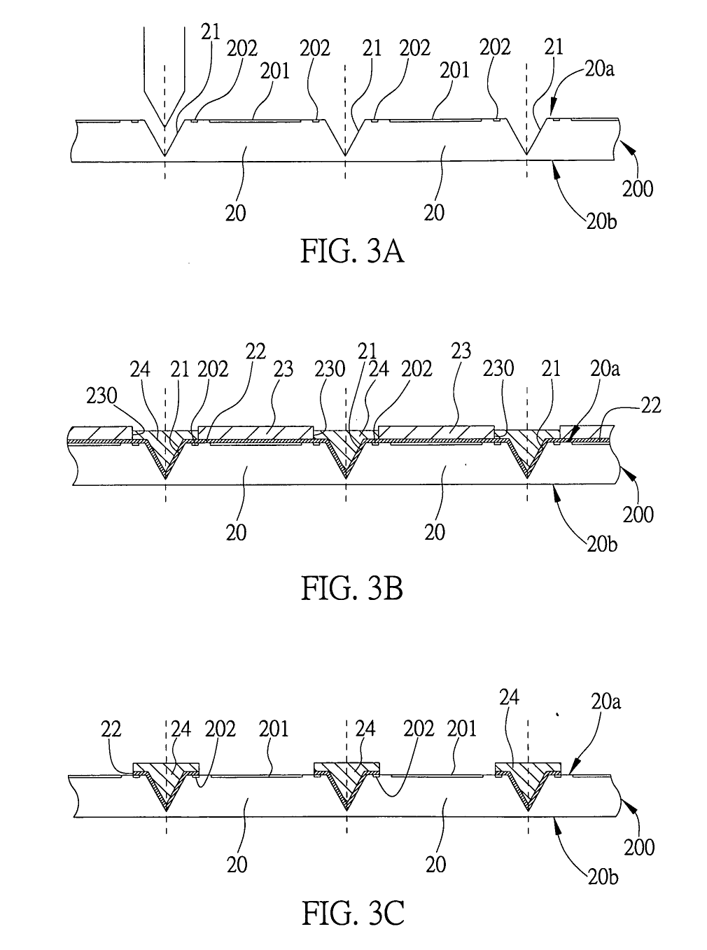

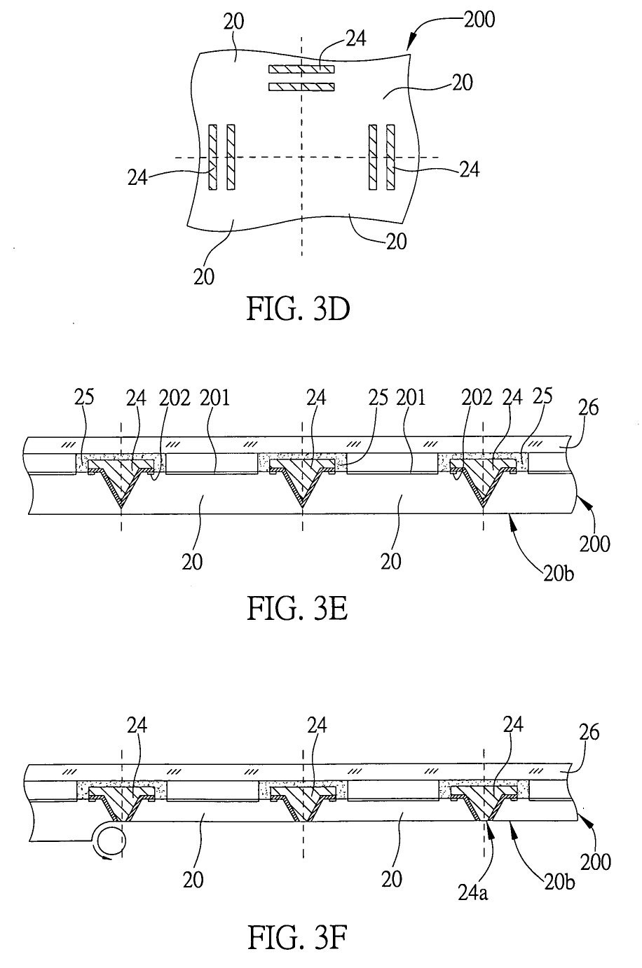

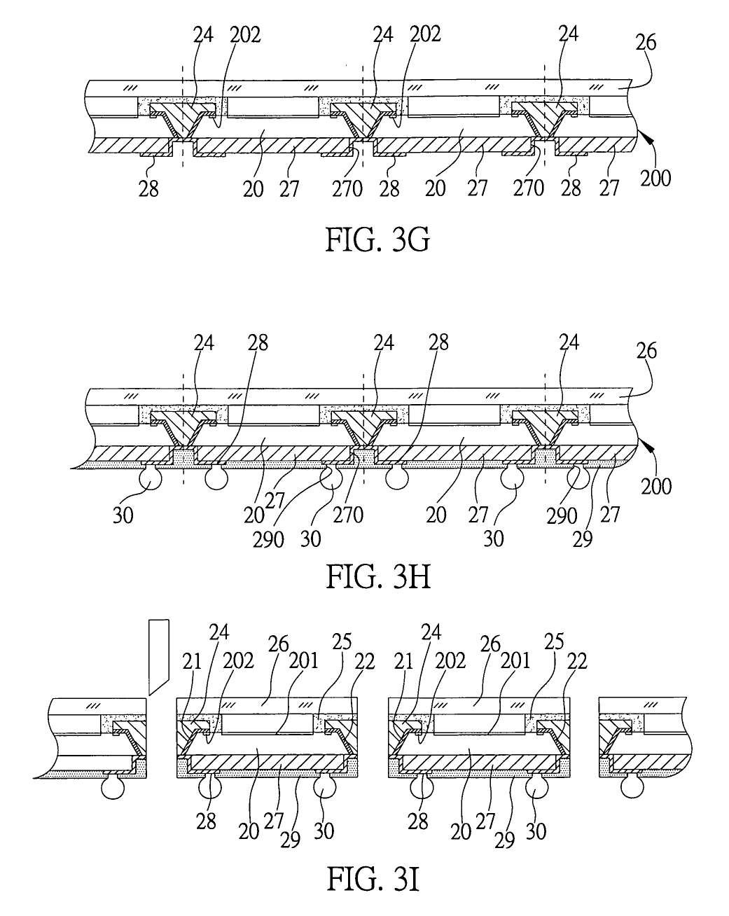

Referring to FIGS. 3A to 3I, which are schematic views of a sensor semiconductor packages and a fabrication method thereof according to a preferred embodiment of the present invention.

As shown in FIG. 3A, a wafer 200 having a plurality of sensor chips 20 is provided. The wafer 200 and the sensor chips 20 all have an active surface 20a and a non-active surface 20b opposing thereto. A sensor area 201 and a plurality of bond pads 202 are formed on the active surface 20a of each of the sensor chips 20. A plurality of grooves 21 are formed between the bond pads 202 of the chips 20 adjacent to each other, wherein the grooves 21 can be in, for example, V-shape or other shapes.

As shown in FIG. 3B, sputtering or vaporizing methods are used to form a conductive layer 22 on the active surfaces 20a of the wafer 200 and on the grooves 21. The conductive layer 22 is an under bottom metal (UBM) layer and the material thereof can be, for example, Ti/Cu/Ni, TiW/Au, Al/NiV/Cu, Ti/NiV/Cu, TiW/Ni, Ti/Cu/Cu, and Ti/Cu/Cu/Ni and etc. . . .

Subsequently, a resist layer 23 is formed on the conductive layer 22, and the resist layer 23 formed has openings 230 opened at positions corresponding to the grooves 21 and the bond pads 202 of the sensor chips 20.

Then, metal layers 24 are formed in the openings 230 of the resist layer 23 through electroplating, allowing the metal layers 24 to fill the space in the grooves 21 and to be electrically connected to the bond pads 202 on the active surface 20a of every adjacent chips 20, where the metal layers 24 are thick copper layers with a thickness of 5-50 μm.

As shown in FIGS. 3C and 3D, in which FIG. 3D is the top view showing the adjacent sensor chips in FIG. 3C, the resist layer 23 and a portion of the conductive layer 22 covered thereby are removed, so as to form a plurality of metal layers 24 which are electrically connected to the bond pads 202 of two adjacent sensor chips 20 on the active surface 20a of the wafer 200.

As shown in FIG. 3E, a transparent object 26 such as a glass is attached on the wafer 200 via an adhesive layer 25. The adhesive layers 25 are attached on peripheries of the sensor chips 20, without covering the image sensor areas 201 of the sensor chips 20, allowing the transparent object 26 to seal the sensor areas 201 of the sensor chips 20.

As shown in FIG. 3F, a thinning process such as grinding is performed on the non-active surface 20b of the wafer 200 until it reaches the metal layers 24, so as to expose a portion of the metal layers 24 from the non-active surface 20b and allow the metal layers 24 to have a flat bottom surface 24a which is flush with the non-active surface 20b of the wafer 200.

As shown in FIG. 3G, a cover layer 27 is formed on the non-active surface 20b of the wafer 200 in a way that the cover layer 27 has openings 270 to expose the portion of the metal layers 24 therefrom, where a size of each of the openings 270 can be selectively about 5-20 μm, preferably 10 μm, larger than a bottom surface of the exposed portion of the metal layers 24. As such, even if there is a departure in the position of the opening 270 of the cover layer 27, the conductive wirings 28 formed on the cover layer 27 in a latter procedure can be electrically connected to the metal layers 24 effectively, thereby providing a wider process window. The cover layer 27 can be a dielectric layer being made of Benzo-Cyclo-Buten (BCB) or Polyimide.

Then, through a wiring patterning process, a plurality of conductive wirings 28 are formed on the cover layer 27 and are electrically connected to the portion of the metal layers 24 exposing from the opening 270 of the cover layer 27. The material of the conductive circuits 28 can be Ti/Cu/Ni or Ti/Cu/Cu/Ni.

As shown in FIG. 3H, a solder resist layer 29 is formed on the cover layer 27 and conductive wirings 28, and allowing the solder resist layer 29 to have openings 290 to expose terminals of the conductive wirings 28, which is used for deposing conductive elements 30 such as solder balls thereon.

As shown in FIG. 3I, a cutting process is performed along paths between every adjacent sensor chips 20, so as to form a plurality of sensor packages.

Through the foregoing fabrication method, a sensor semiconductor package according to a preferred embodiment of the present invention is provided, comprising:

a sensor chip 20 having an active surface 20a and a non-active surface 20b opposing thereto, wherein the active surface 20a is formed with a sensor area 201 and a plurality of bond pads 202 thereon, a groove 21 is formed on a side of the sensor chip 20 and a metal layer 24 is formed in the groove 21 and is electrically connected to the bond pads 202; a transparent body 26 mounted on the active surface 20a of the sensor chip 20 for sealing the image sensor area 201; a cover layer 27 formed on the non-active surface 20b of the sensor chip 20 and having an opening 270 for exposing a bottom of the metal layers 24; a conductive wiring 28 formed under the cover layer 27 and electrically connected to the bottom of the metal layers 24; a solder resist layer 29 formed under the cover layer 27 and conductive wiring 28 and having openings 290 for exposing a terminal of the conductive wiring 28; and a conductive element 30 formed in the opening 290 of the solder resist layer 29.

The sensor semiconductor package further comprises a conductive layer 22 formed between the sensor chip 20 and the metal layers 24. Further, the transparent body 26 is a glass attached to sensor chip 20 via an adhesive layer 25, which covers metal layers 24. The metal layers 24 have a flat bottom 24a, which is flush with the non-active surface 20b of the sensor chip 20, for providing a good electrical connection with the conductive wirings 28.

Accordingly, the sensor semiconductor package and the fabrication method thereof disclosed in the present invention, mainly involve forming a plurality of grooves on a wafer having a plurality of sensor chips, at positions between every adjacent sensor chips, and forming metal layers in grooves for electrically connecting the bond pads on the active surfaces of adjacent chips. This is then followed by attaching a transparent body to seal the sensor areas of the sensor chips, and performing a thinning process on the non-active surfaces of the sensor chips until the metal layers are exposed from the non-active surfaces, so as to prevent the position error in the thinning process, as well as position error of the metal layers, which may subsequently cause poor electrical connection of the conductive circuit on one side of the non-active surface of the chip. After that, a cover layer is formed on the non-active surfaces of the wafer and has openings for exposing the metal layers, which are used for forming conductive wirings on the cover layer, where the conductive wirings formed is allowed to electrically connect to the portion of the metal layers exposing from the openings of the cover layer. A solder resist layer is subsequently formed on the cover layer and the conductive wirings, and has openings for exposing terminals of the conductive wirings, that is exposed for deposing conductive elements thereon. After a cutting process is performed between each adjacent sensor chips, a plurality of sensor semiconductor packages are obtained.

As such, the problem of poor electrical connection of the circuits or even damages in chips due to a shift in position for forming the grooves on the back side of the wafer in the prior art and can be prevented. Moreover, the problem of breakage due to concentrated stress as a result of a sharp contact between the side surface of the semiconductor chip and the active surface of the wiring connecting point in the condition of a beveled side surface of the package can be also prevented.

### Second Embodiment

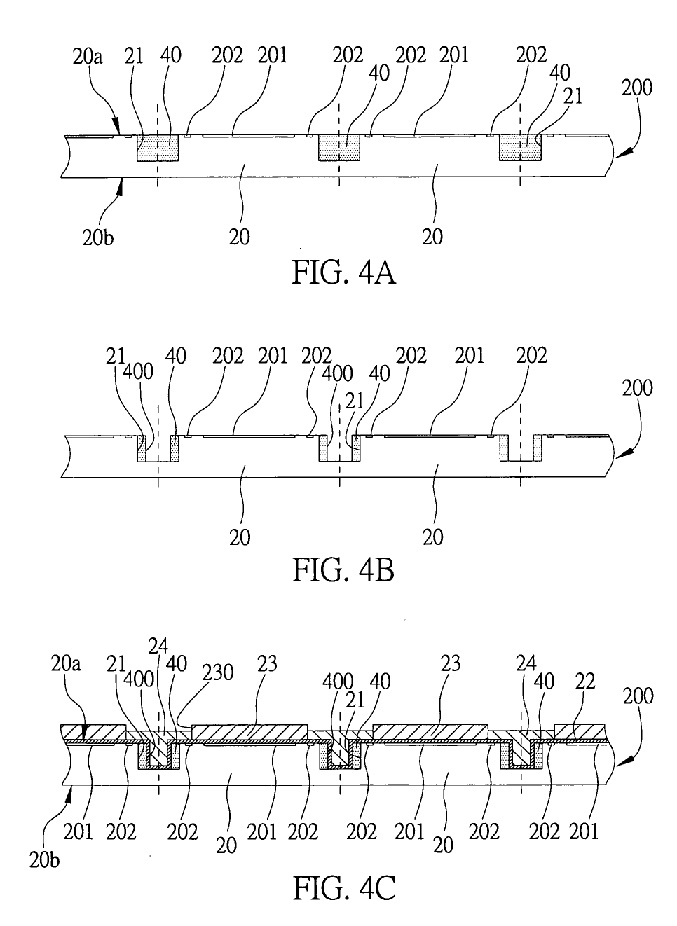

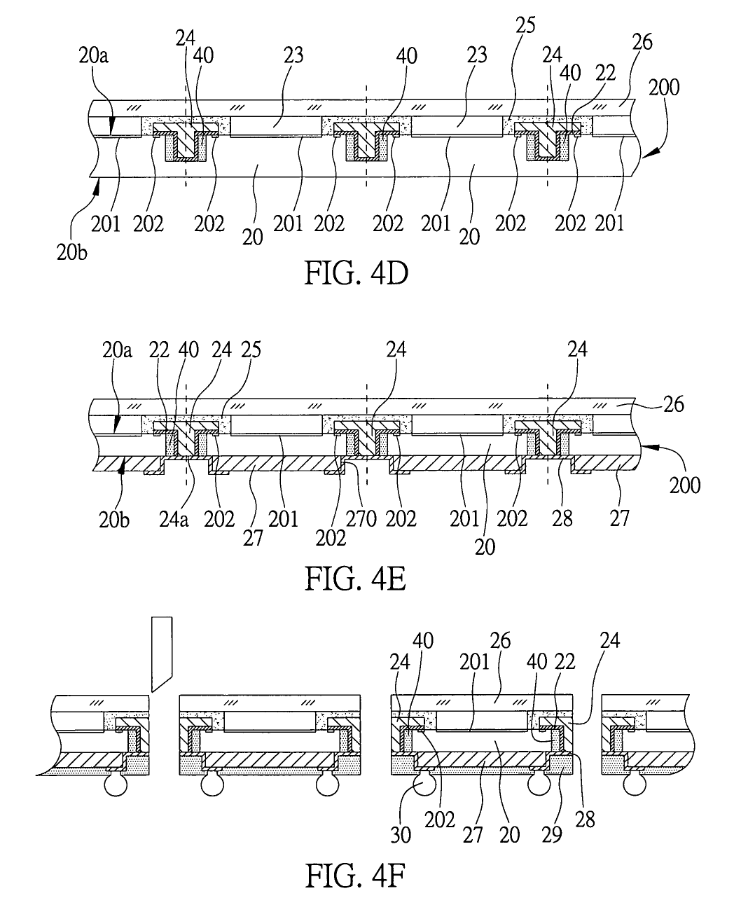

Referring to FIGS. 4A to 4F, which are schematic views of a sensor semiconductor package and a fabrication method thereof according to another preferred embodiment of the present invention. For simplifying the description, the corresponding or equivalent elements in this embodiment and the first embodiment will be described with the same reference numeral.

The second embodiment is similar to the first embodiment, except that the following steps could be performed after the grooves are formed between the bond pads on the active surfaces of adjacent sensor chips, which comprises: filling an insulting layer in the grooves of the wafer; forming openings passing through the insulating layer so as to form the metal layers therein and allow the metal layers to electrically connected to the bond pads on the active surfaces of adjacent sensor chips. Thus increases the adherence and the insulation between the sensor chips and the metal layers by the insulating layer.

As shown in FIG. 4A, a wafer 200 having a plurality of sensor chips 20 is provided. The wafer 200 and the sensor chips 20 all have an active surface 20a and a non-active surface 20b opposing thereto. A sensor area 201 and a plurality of bond pads 202 are formed on the active surface 20a of each of the sensor chips 20. A plurality of grooves 21 are formed between the bond pads 202 of the chips 20 adjacent to each other. Then, an insulating layer 40 made of such as polyimide is filled in the grooves 21.

As shown in FIG. 4B, etching or cutting the insulting layer 40 to form openings 400 passing therethrough, wherein a width of each of the openings 400 is smaller than that of each of the grooves 21 such that a portion of the insulating layer 40 still deposed on lateral sides of the sensor chips 20.

As shown in FIG. 4C, a conductive layer 22 is further formed on the active surfaces 20a of the wafer 200, on the portion of the insulating layer 40, and the grooves 21. Subsequently, a resist layer 23 is formed on the conductive layer 22, and the resist layer 23 formed has openings 230 opened at positions corresponding to the grooves 21 and the bond pads 202 of the sensor chips 20.

Then, metal layers 24 are formed in the openings 230 of the resist layer 23 through electroplating, allowing the metal layers 24 to fill the space in the opening 400 of the insulating layer 40 and to be electrically connected to the bond pads 202 on the active surface 20a of every adjacent chips 20, where the portion of the insulating layer 40 and the conductive layer 22 are deposed between the metal layers 24 and the sensor chip 20.

Since the lateral sides of the sensor chips 20 are still covered with the portion of the insulating layer 40, the adherence and insulation between the sensor chips 20 and the metal layers 24 are increased.

As shown in FIG. 4D, the resist layer 23 and a portion of the conductive layer 22 covered thereby are removed. A transparent object 26 is attached on the wafer 200 by an adhesive layer 25. The adhesive layers 25 is attached on peripheries of the sensor chips 20, without covering the sensor areas 201 of the sensor chips 20, allowing the transparent object 26 to seal the sensor areas 201 of the sensor chips 20.

As shown in FIG. 4E, a thinning process is performed on the non-active surface 20b of the wafer 200 until it reaches the metal layers 24, so as to expose a portion of the metal layers 24 from the non-active surface 20b and allow the metal layers 24 to have a flat bottom surface 24a which is flush with the non-active surface 20b of the wafer 200.

After that, a cover layer 27 is formed on the non-active surface 20b of the wafer 200 in a way that the cover layer 27 has openings 270 to expose the portion of the metal layers 24 therefrom. Through a wiring patterning process, a plurality of conductive wirings 28 are formed on the cover layer 27 and are electrically connected to the portion of the metal layers 24 exposing from the opening 270 of the cover layer 27.

As shown in FIG. 4F, a solder resist layer 29 is formed on the cover layer 27 and conductive wirings 28, and allowing the solder resist layer 29 to have openings 290 to expose terminals of the conductive wirings 28, which is used for deposing conductive elements 30 such as solder balls thereon. A cutting process is performed along paths between every adjacent sensor chips 20, so as to form a plurality of sensor semiconductor packages.

The present invention has been described using exemplary preferred embodiments. However, it is to be understood that the scope of the present invention is not limited to the disclosed embodiments. On the contrary, it is intended to cover various modifications and similar arrangements. The scope of the claims, therefore, should be accorded the broadest interpretation so as to encompass all such modifications and similar arrangements.

What is claimed is:

1. A fabrication method of sensor semiconductor packages, comprising:
providing a wafer having a plurality of sensor chips, each of the wafer and the sensor chips having an active surface and an non-active surface opposing thereto, a sensor area and a plurality of bond pads formed on the active surface, and a plurality of grooves formed between the bond pads of the active surfaces of adjacent sensor chips;
forming metal layers on positions corresponding to grooves and electrically connecting the bond pads of adjacent sensor chips;
attaching a transparent body on the sensor chips to seal the sensor areas;
performing a thinning process on the non-active surfaces of the wafer until respective portions of the metal layers are exposed from the non-active surfaces;
forming a cover layer having openings on the non-active surfaces of the wafer for exposing the respective portions of the metal layers;
forming conductive wirings on the cover layer to electrically connect to the respective portions of the metal layers exposed from the openings of the cover layer;
forming a solder resist layer having openings on the cover layer and the conductive wirings for exposing terminals of the conductive wirings for deposing conductive elements thereon; and
performing a cutting process cutting between adjacent sensor chips, so as to obtain a plurality of sensor semiconductor packages.

2. The fabrication method of the sensor semiconductor packages of claim 1, wherein the step of forming the metal layers comprises the steps of:
forming a conductive layer on the active surfaces of the wafer and the grooves;
forming a resist layer on the conductive layer with openings corresponding in position to the grooves
electroplating the metal layers in the openings of the resist layer, such that the metal layers are filled in the grooves and electrically connected to the bond pads on the active surfaces of adjacent sensor chips; and
removing the resist layer and a portion of the conductive layer thereunder, such that the metal layers are formed between adjacent sensor chips.

3. The fabrication method of the sensor semiconductor packages of claim 2, wherein the conductive layer is an under bottom metal (UBM) layer being made of one selected from a group consisting of Ti/Cu/Ni, TiW/Au, Al/NiV/Cu, Ti/NiV/Cu, Tiw/Ni, Ti/Cu/Cu, and Ti/Cu/Cu/Ni, and is formed on the active surfaces of the wafer and the grooves by one of sputtering and evaporation.

4. The fabrication method of the sensor semiconductor packages of claim 1, wherein the metal layers are copper layers of 5-50 μm in thickness.

5. The fabrication method of the sensor semiconductor packages of claim 1, wherein the transparent body is a glass, and the transparent body is attached on the sensor chips to seal the sensor areas by an adhesive layer being on peripheries of the sensor chips and not covering the sensor areas of the sensor chips.

6. The fabrication method of the sensor semiconductor packages of claim 1, wherein after the thinning process, the metal layers have a flat bottom which is flush with the thinned non-active surface of the wafer.

7. The fabrication method of the sensor semiconductor packages of claim 1, wherein a size of each of the openings of the cover layer is 5-20 μm larger than that of the respective portions of the metal layers exposed therefrom.

8. The fabrication method of the sensor semiconductor packages of claim 7, wherein the size of each of the openings of the cover layer is 10 μm larger than that of the respective portions of the metal layers exposed therefrom.

9. The fabrication method of the sensor semiconductor packages of claim 1, wherein the cover layer is made of one of Benzo-Cyclo-Butene (BCB) and polyimide.

10. The fabrication method of the sensor semiconductor packages of claim 1, wherein the conductive wirings are made of one of Ti/Cu/Ni and Ti/Cu/Cu/Ni.

11. The fabrication method of the sensor semiconductor packages of claim 1, wherein the step of forming the metal layers comprises the steps of:
filling an insulting layer in the grooves of the wafer;
forming openings passing through the insulating layer
forming a conductive layer on the active surfaces of the wafer, the insulating layer and the grooves;
forming a resist layer on the conductive layer with openings corresponding in position to the grooves
electroplating the metal layers in the openings of the resist layer, such that the metal layers are filled in the openings passing through the insulating layer and electrically connected to the bond pads on the active surfaces of adjacent sensor chips; and
removing the resist layer and a portion of the conductive layer thereunder, such that the metal layers are formed between adjacent sensor chips.

12. The fabrication method of the sensor semiconductor packages of claim 10, wherein a size of each of the openings of the insulating layer is smaller than that of the grooves for covering lateral sides of the sensor chips by the insulation layer.

13. A sensor semiconductor package, comprising:
a sensor chip having an active surface and a non-active surface opposing thereto, wherein the active surface is formed with a sensor area and a plurality of bond pads thereon, a groove is formed on a side of the sensor chip and a metal layer is formed in the groove and is electrically connected to the bond pads;
a transparent body mounted on the active surface of the sensor chip for sealing the sensor area;
a cover layer formed on the non-active surface of the sensor chip and having an opening for exposing a bottom of the metal layers;
a conductive wiring formed under the cover layer and electrically connected to the bottom of the metal layers;
a solder resist layer formed under the cover layer and conductive wiring and having openings for exposing a terminal of the conductive wiring; and
a conductive element formed in the opening of the solder resist layer.

14. The sensor semiconductor package of claim 13, further comprising a conductive layer formed between the sensor chip and the metal layers.

15. The sensor semiconductor package of claim 14, wherein the conductive layer is an under bottom metal (UBM) layer being made of one selected from a group consisting of Ti/Cu/Ni, TiW/Au, Al/NiV/Cu, Ti/NiV/Cu, Tiw/Ni, Ti/Cu/Cu, and Ti/Cu/Cu/Ni.

16. The sensor semiconductor package of claim 13, wherein the metal layers are thick copper layers of 5-50 μm in thickness.

17. The sensor semiconductor package of claim 13, wherein the transparent body is a glass, and the transparent body is attached on the sensor chip to seal the sensor area by an adhesive layer being on peripheries of the sensor chip and not covering the sensor area of the sensor chip.

18. The sensor semiconductor package of claim 13, wherein the metal layers have a flat bottom which is flush with the thinned non-active surface of the wafer.

19. The sensor semiconductor package of claim 13, wherein a size of each of the openings of the cover layer is larger than that of the respective portions of the metal layers exposed therefrom.

20. The sensor semiconductor package of claim 13, wherein the cover layer is made of one of Benzo-Cyclo-Butene (BCB) and polyimide.

21. The sensor semiconductor package of claim 13, wherein the conductive circuit is made of one of Ti/Cu/Ni and Ti/Cu/Cu/Ni.

22. The sensor semiconductor package of claim 13, further comprising an insulating layer formed between a lateral side of the sensor chip and the metal layers.

23. The sensor semiconductor package of claim 22, further comprising a conductive layer formed between the insulating layer and the metal layers.
